(19) United States
(12) Patent Application Publication
(10) Pub. No.: US 2009/0160511 A1
(43) Pub. Date: Jun. 25, 2009

(54) PLL CIRCUIT

(76) Inventor: Toru Sudo, Chiba-shi (JP)

Correspondence Address: BRINKS HOFER GILSON & LIONE, P.O. BOX 10395, CHICAGO, IL, 60610, US

(21) Appl. No.: 12/337,101

(22) Filed: Dec. 17, 2008

(30) Foreign Application Priority Data
Dec. 19, 2007 (JP) JP2007-327295

(51) Int. Cl. H03L 7/06

(52) U.S. Cl. 327/157

(57) ABSTRACT

The PLL circuit includes: a voltage control oscillating circuit including: a voltage-current converter circuit; a current adder; and a current control oscillating circuit, the voltage control oscillating circuit outputting a pulse having a frequency corresponding to a control voltage and a control current; a phase detector which outputs a first control signal and a second control signal based on a phase difference between the pulse and a reference pulse having a frequency which should be generated by the voltage control oscillating circuit; a first charge pump circuit which outputs one of a first charge current and a first discharge current in accordance with the first control signal; a loop filter which generates the control voltage in accordance with the one of the first charge current and the first discharge current, and then outputs the generated control voltage to the voltage control oscillating circuit; and a second charge pump circuit which generates the control current serving as one of a second charge current and a second discharge current in accordance with the second control signal, and then outputs the generated control current to the voltage control oscillating circuit.

### RELATED APPLICATIONS

This application claims priority under 35 U.S.C. §119 to Japanese Patent Application No. JP2007-327295 filed on Dec. 19, 2007, the entire content of which is hereby incorporated by reference.

### BACKGROUND OF THE INVENTION

1. Field of Invention

The present invention relates to a phase-locked loop (PLL) circuit, and more particularly, to a PLL circuit in which occurrence of characteristic variations is reduced.

2. Description of the Related Art

Conventionally, a PLL circuit is provided in a semiconductor integrated circuit, and is widely used as a pulse generation circuit particularly in the wireless communication field such as a cell phone, a wireless local area network (LAN), etc.

As illustrated in FIG. 6, the above-mentioned PLL circuit includes a phase comparator 100, a charge pump circuit 101, a loop filter 102, and a voltage control oscillating circuit (VCO) 103.

The phase comparator 100 performs a phase comparison between an output pulse which is output from the PLL circuit and an input pulse which is input to the phase comparator 100. When the phase of the output pulse is delayed compared with the input pulse, the phase comparator 100 outputs, to the charge pump circuit 101, a control signal UP for causing a charge-up current IUP to flow, whereas when the phase of the output pulse is advanced compared with the input pulse, the phase comparator 100 outputs, to the charge pump circuit 101, a control signal DN for causing a charge-down current IDN to flow.

Upon input of the control signal UP, the charge pump circuit 101 outputs the charge-up current IUP to the loop filter 102. On the other hand, upon input of the control signal DN, the charge pump circuit 101 outputs the charge-down current IDN to the loop filter 102.

The loop filter 102 is a low-pass filter which averages direct-current signals input from the charge pump circuit 101, and converts the averaged signal into a direct-current signal containing fewer alternating-current components. The loop filter 102 sets, using a time constant, the speed of frequency change of the VCO 103 provided downstream thereof. Specifically, when the time constant is long, the oscillation frequency of the VCO 103 is changed slowly, whereas when the time constant is short, the oscillation frequency is changed quickly in response to the input pulse.

The VCO 103 controls the oscillation frequency of an output pulse in accordance with the voltage level of a direct-current signal which is input from the loop filter 102.

Further, the VCO 103 includes a voltage-current converter circuit 103A for converting a voltage signal of a direct current into a current signal and a current control oscillating circuit 103B for determining an oscillation frequency based on the current output from the voltage-current converter circuit 103A.

As the above-mentioned loop filter 102, there is employed a complete integral filter circuit as illustrated in FIG. 7 (for example, see “How to use PLL-IC” by Masayasu Hata and Keisuke Furukawa, Akiba Press, newly-bound version, June, 1987 (hereinafter, referred to as Non-Patent Document 1)).

Here, a switching circuit 101′ is a component used in place of the charge pump circuit 101 of FIG. 6, and serves to apply a voltage to the complete integral filter circuit (loop filter 102).

Further, as illustrated in FIG. 8, there is employed a current-input voltage-output type as the loop filter 102 in which a capacitor C2 and a resistor R2 are connected in series. The loop filter 102 adds together a voltage stored in the capacitor C2 and a voltage generated, by a charge current flowing into the capacitor C2, between the terminals of the resistor R2, and then outputs a result of the addition to the voltage-current converter circuit 103A provided in the VCO 103 (for example, see JP 2005-260446 A (hereinafter, referred to as Patent Document 1)).

With the above structure, in addition to the voltage stored in the capacitor C2, the voltage generated at the resistor R2 is output to the VCO provided downstream of the loop filter 102. Thus, as illustrated in FIG. 9, it is possible to enhance a response characteristic for a voltage characteristic by the voltage across the resistor R2.

Here, r2 represents a resistance value of the resistor R2, IF1 represents current values of the charge-up current IUP and the charge-down current IDN, which are output by the charge pump circuit 101, and c2 represents a capacitance value of the capacitor C2.

However, as illustrated in FIG. 9, the loop filter 102 employed in Non-Patent Document 1 and Patent Document 1, which is configured as the complete integral filter circuit, has such a response characteristic as to output a sharp voltage output signal.

Accordingly, it is difficult for the CMOS process to provide an appropriate response characteristic to the voltage-current converter circuit 103A of the VCO 103 so that the voltage-current converter circuit 103A can deal with this sharp change when converting the input sharp voltage output signal from voltage to current. In reality, as illustrated in FIG. 10, a waveform of the current output signal after the voltage-current conversion shows gradual changes.

As a result, even if the response characteristic of the loop filter 102 is improved, it is impossible to carry out a theoretical design based on device characteristics, due to the fact that the response characteristic of the voltage-current converter circuit 103A of the VCO 103 is low.

Besides, variation in voltage-current conversion speed caused by process variation results in variation in response characteristic of the PLL circuit, which leads to a problem that more products fail to satisfy the specification thereof when mass-produced.

### SUMMARY OF THE INVENTION

In view of the above-mentioned circumstances, the present invention has been made, and has an object to provide a PLL circuit having an improved response characteristic for frequency control compared with a conventional PLL circuit, by speeding up voltage-current conversion operation in which a current for controlling a current control oscillating circuit provided in a VCO is generated.

A PLL circuit according to the present invention includes: a voltage control oscillating circuit including: a voltage-current converter circuit; a current adder; and a current control oscillating circuit, the voltage control oscillating circuit outputting a pulse having a frequency corresponding to a control voltage and a control current; a phase detector which outputs a first control signal and a second control signal based on a phase difference between the pulse and a reference pulse having a frequency which should be generated by the voltage control oscillating circuit; a first charge pump circuit which outputs one of a first charge current and a first discharge current in accordance with the first control signal; a loop filter which generates the control voltage in accordance with the one of the first charge current and the first discharge current, and then outputs the generated control voltage to the voltage control oscillating circuit; and a second charge pump circuit which generates the control current serving as one of a second charge current and a second discharge current in accordance with the second control signal, and then outputs the generated control current to the voltage control oscillating circuit.

In the PLL circuit according to the present invention, the voltage-current converter circuit converts the control voltage into a current, and the current adder adds together the converted current and the control current to supply a current obtained by the adding to the current control oscillating circuit as a frequency control current.

In the PLL circuit according to the present invention, the loop filter includes a capacitor which is inserted between an output terminal of the first charge pump circuit and a ground point.

As has been described above, according to the present invention, the current adder circuit adds together a current obtained by converting, at the voltage-current converter circuit, the control voltage which is generated from the loop filter in accordance with the first charge current and the first discharge current output from the first charge pump and the control current generated from the second charge pump circuit, and then, the current control oscillating circuit is driven using a current obtained by the adding. Accordingly, it is possible to notify the current control oscillating circuit of a sharp voltage change through the control current, and, owing to the control current, a frequency change having a sharp response characteristic can be realized in the current control oscillating circuit.

Specifically, according to the present invention, the function of the conventional loop filter is actually realized by a combination of the capacitor (loop filter), the second charge pump circuit, and the current adder circuit. As a result, it is possible to suppress influence on the response characteristic of the filter, resulting from variation in resistance value and capacitance value which is observed in a conventional case in which only a resistor and a capacitor are formed. Thus, a filter characteristic which exhibits less variation compared with the conventional case is realized.

As a result, according to the present invention, owing to the provision of the current adder circuit, compared with the conventional case in which a loop filter is configured of a resistor and a capacitor, an ideal complete integral filter can be realized from the perspective of the current control oscillating circuit.

### BRIEF DESCRIPTION OF THE DRAWINGS

In the accompanying drawings:

FIG. 1 is a block diagram illustrating a configuration example of a PLL circuit according to an embodiment of the present invention;

FIG. 2 is a waveform diagram illustrating an operation example of the PLL circuit of FIG. 1;

FIG. 3 is another waveform diagram illustrating another operation example of the PLL circuit of FIG. 1;

FIG. 4 is a conceptual diagram illustrating circuit examples of a voltage-current converter circuit and a current adder circuit of FIG. 1;

FIG. 5 is a conceptual circuit diagram illustrating a configuration example of a current control oscillating circuit of FIG. 1;

FIG. 6 is a block diagram illustrating a general configuration of a PLL circuit;

FIG. 7 is a block diagram illustrating a configuration of a conventional PLL circuit;

FIG. 8 is a block diagram illustrating a configuration of another conventional PLL circuit;

FIG. 9 is a waveform diagram for describing operation of the PLL circuit of FIG. 8; and

FIG. 10 is another waveform diagram for describing the operation of the PLL circuit of FIG. 8.

### DETAILED DESCRIPTION OF THE PREFERRED EMBODIMENTS

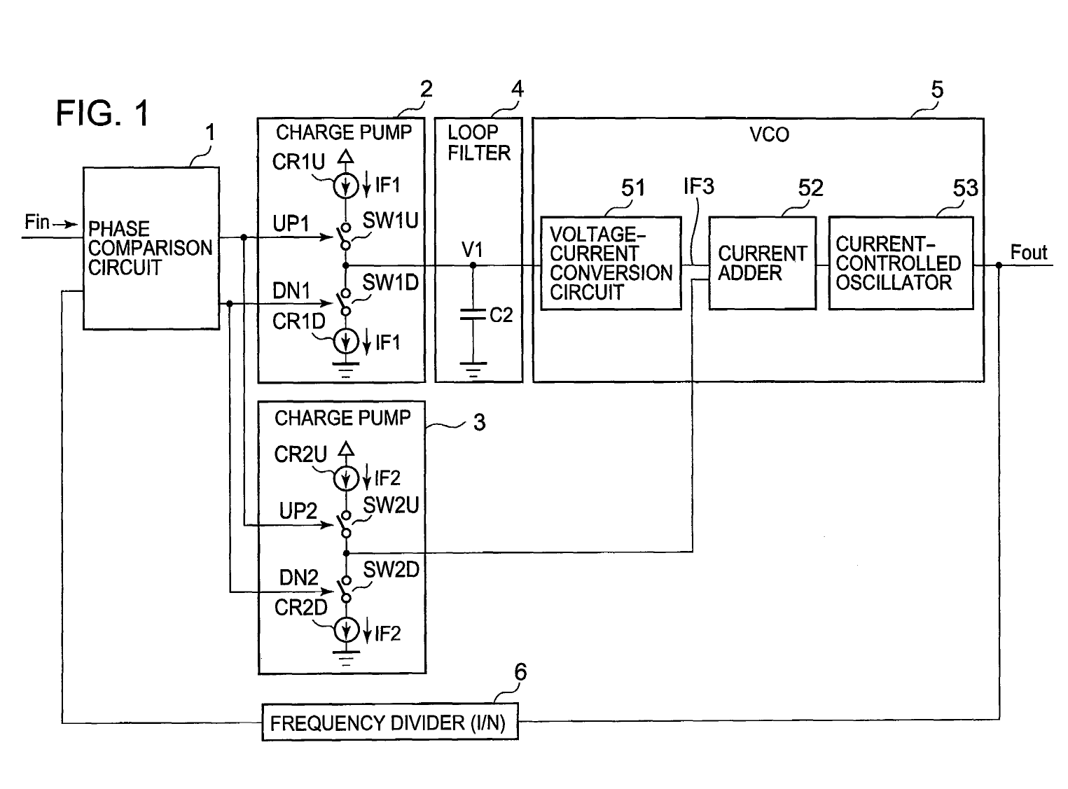

Hereinbelow, a phase-locked loop (PLL) circuit according to an embodiment of the present invention is described with reference to the drawings. FIG. 1 is a block diagram illustrating a configuration example of the PLL circuit according to the embodiment of the present invention.

In FIG. 1, the PLL circuit according to this embodiment includes a phase comparator circuit 1, a charge pump 2, a charge pump 3, a loop filter 4, a voltage control oscillating circuit (VCO) 5, and a frequency divider 6. Further, the VCO 5 includes a voltage-current converter circuit 51, a current adder circuit 52, and a current control oscillating circuit 53.

The frequency divider 6 divides, by N, a frequency fₒᵤₜ of a pulse signal Fₒᵤₜ which is output from the VCO 5, and then outputs a divided frequency pulse signal having a frequency of fₒᵤₜ/N In this manner, the frequency fₒᵤₜ of the pulse signal Fₒᵤₜ is set as an N-fold frequency of a frequency fᵢₙ of a reference pulse signal Fᵢₙ.

The phase comparator circuit 1 detects a phase difference between the above-mentioned divided frequency pulse signal and the reference pulse signal Fᵢₙ having a frequency of 1/N of the frequency which should be generated from the VCO 5, and then outputs a control signal UP1 and a control signal DN1 to the charge pump 2 at predetermined intervals for a predetermined control period as a result of the comparison. The control signal UP1 and the control signal DN1 are used to control, in accordance with that phase difference, which one of a first charge current and a first discharge current is to be output as a current signal IF1.

Further, the phase comparator circuit 1 outputs to the charge pump 3 a control signal UP2 and a control signal DN2 which are used to control, in accordance with the above-mentioned phase difference, which one of a second charge current and a second discharge current is to be output as a current signal IF2.

Here, when the phase of the divided frequency pulse signal is delayed compared with the above-mentioned reference pulse signal Fᵢₙ, the phase comparator circuit 1 outputs the control signal UP1 which causes the charge pump 2 to output the first charge current as the current signal IF1. On the other hand, when the phase of the divided frequency pulse signal is advanced compared with the above-mentioned reference pulse signal Fᵢₙ, the phase comparator circuit 1 outputs the control signal DN1 which causes the charge pump 2 to output the first discharge current as the current signal IF1.

Further, when the phase of the divided frequency pulse signal is delayed compared with the above-mentioned reference pulse signal Fᵢₙ, the phase comparator circuit 1 outputs the control signal UP2 which causes the charge pump 3 to output the second charge current as the current signal IF2. On the other hand, when the phase of the divided frequency pulse signal is advanced compared with the above-mentioned reference pulse signal Fᵢₙ, the phase comparator circuit 1 outputs the control signal DN2 which causes the charge pump 3 to output the second discharge current as the current signal IF2.

In the charge pump 2, between a power supply voltage line and a ground line, a constant current source CR1U, a switch SW1U, a switch SW1D, and a constant current source CR1D are connected in series in the stated order. A node between the switch SW1U and the switch SW1D serves as an output terminal, from which the above-mentioned current signal IF1 is output to the loop filter 4.

Further, upon input of the above-mentioned control signal UP1, the charge pump 2 sets the switch SW1U in an ON-state, and then outputs the first charge current as the current signal IF1 from the output terminal. On the other hand, upon input of the control signal DN1, the charge pump 2 sets the switch SW1D in the ON-state, and then outputs the first discharge current as the current signal IF1 from the output terminal.

In the charge pump 3, between the power supply voltage line and the ground line, a constant current source CR2U, a switch SW2U, a switch SW2D, and a constant current source CR2D are connected in series in the stated order. A node between the switch SW2U and the switch SW2D serves as an output terminal, from which the above-mentioned current signal IF2 is output to the VCO 5.

Further, upon input of the above-mentioned control signal UP2, the charge pump 3 sets the switch SW2U in the ON-state, and then outputs the second charge current as the current signal IF2 from the output terminal. On the other hand, upon input of the control signal DN2, the charge pump 3 sets the switch SW2D in the ON-state, and then outputs the second discharge current as the current signal IF2 from the output terminal.

The loop filter 4 includes a capacitor C2, and by charging/discharging the capacitor C2 with the direct-current signal IF1 which contains a ripple and is output from the charge pump 2, the loop filter 4 performs integral operation, thereby outputting a control voltage V1 to the VOC 5.

The voltage-current converter circuit 51 converts the input control voltage V1 into a current IF3 having a current value corresponding to the voltage value, and then outputs the current IF3 obtained from this conversion to the current adder circuit 52.

The current adder circuit 52 adds together the above-mentioned current IF3 and the current signal IF2, and then outputs a current IF4 obtained from the addition to the current control oscillating circuit 53.

The current control oscillating circuit 53 outputs the pulse signal Fₒᵤₜ having the frequency fₒᵤₜ corresponding to the current value of the current IF4 input from the current adder circuit 52.

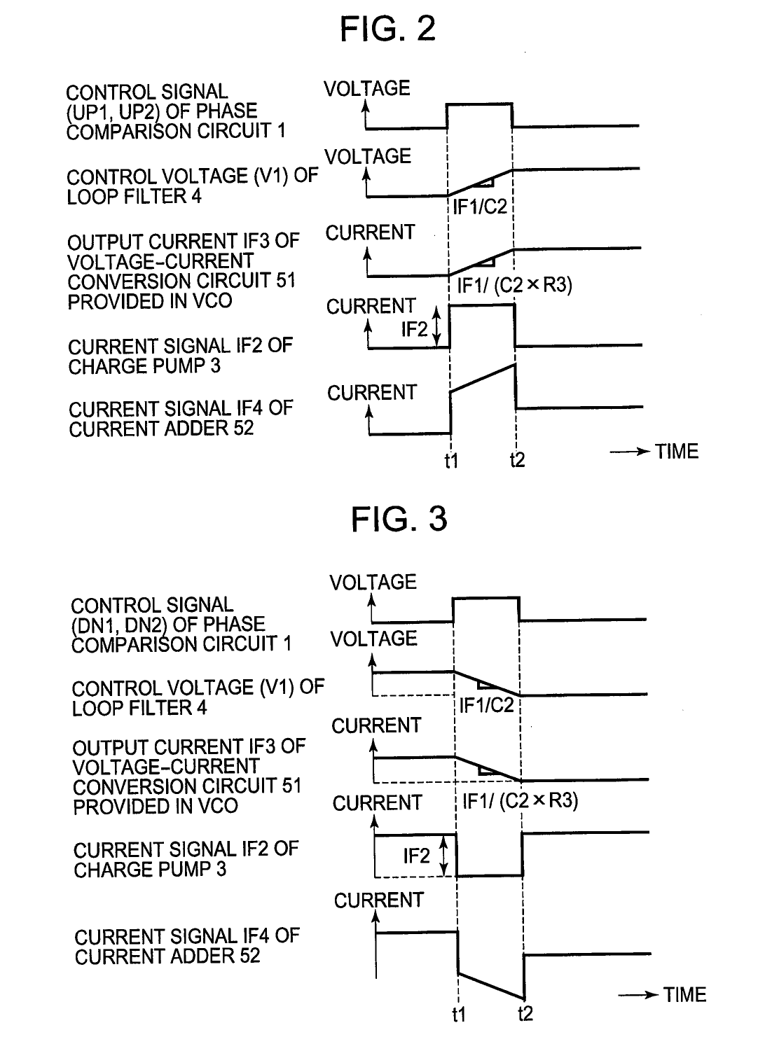

Next, operation of the PLL circuit according to this embodiment is described with reference to FIGS. 1, 2, and 3. FIGS. 2 and 3 are waveform diagrams illustrating operation examples of the respective circuits of FIG. 1.

—Case in which phase of divided frequency pulse signal is delayed compared with reference pulse signal Fᵢₙ (FIG. 2)

At a time point t1, upon start of the above-mentioned control period, the phase comparator circuit 1 detects the phase difference, thereby outputting the control signal UP1 and the control signal UP2.

Then, the charge pump 2 sets the switch SW1U in the ON-state, and then outputs, as the current signal IF1, the first charge current, which is a constant current of the constant current source CR1U, to the loop filter 4.

Consequently, in the loop filter 4, the capacitor C2 is charged with the above-mentioned current signal IF1, and then, the loop filter 4 outputs this charged voltage to the voltage-current converter circuit 51 as the control voltage V1.

Then, the voltage-current converter circuit 51 converts the input control voltage V1 into the current IF3, and then outputs this current IF3 to the current adder circuit 52.

On the other hand, at this time, the charge pump 3 sets the switch SW2U in the ON-state, and then outputs, as the current signal IF2, the second charge current, which is a constant current of the constant current source CR2U, to the current adder circuit 52.

The current adder circuit 52 adds together the current signal IF3 and the current signal IF2 described above, and then outputs the resultant signal to the current control oscillating circuit 53 as the current signal IF4.

As a result, the current control oscillating circuit 53 sets high the frequency fₒᵤₜ of the pulse signal Fₒᵤₜ to be output in accordance with the increased current value.

Next, at a time point t2, upon detecting that the control period has elapsed, the phase comparator circuit 1 stops outputting the control signal UP1 and the control signal UP2.

Due to the stop of input of the control signal UP1, the charge pump 2 sets the switch SW1U in an OFF-state, and then stops outputting the current signal IF1, which is the first charge current.

Consequently, the charge current stops flowing into the loop filter 4. Accordingly, the loop filter 4 holds the current charged voltage, and then outputs this charged voltage to the voltage-current converter circuit 51 as the control voltage V1.

Then, the voltage-current converter circuit 51 converts the input control voltage V1 into the current IF3, and then outputs this current IF3 to the current adder circuit 52.

Further, due to the stop of input of the control signal UP2, similarly to the charge pump 2, the charge pump 3 sets the switch SW2U in the OFF-state, and then stops outputting the current signal IF2, which is the second charge current.

As a result, with respect to the current adder circuit 52, the current signal IF2 is not input, and only the current signal IF3 is input. Accordingly, the current signal IF3 is output as the current signal IF4 without any alteration.

Thus, as a result of this, the current control oscillating circuit 53 generates the frequency fₒᵤₜ in accordance with the pulse signal Fₒᵤₜ which has a frequency corresponding to the current value of the current signal IF3.

—Case in which phase of divided frequency pulse signal is advanced compared with reference pulse signal Fᵢₙ (FIG. 3)

At the time point t1, upon start of the above-mentioned control period, the phase comparator circuit 1 detects the phase difference, thereby outputting the control signal DN1 and the control signal DN2.

Then, the charge pump 2 sets the switch SW1D in the ON-state, and then allows the first discharge current, which is a constant current of the constant current source CR1D, to flow from the loop filter 4 as the current signal IF1.

Consequently, in the loop filter 4, the capacitor C2 is discharged with the above-mentioned current signal IF1, and then, the loop filter 4 outputs this charged voltage after the discharge as the control voltage V1 to the voltage-current converter circuit 51.

Then, the voltage-current converter circuit 51 converts the input control voltage V1 into the current IF3, and then outputs this current IF3 to the current adder circuit 52.

On the other hand, at this time, the charge pump 3 sets the switch SW2D in the ON-state, and then allows the second discharge current, which is a constant current of the constant current source CR2D, to flow from the current adder circuit 52 as the current signal IF2.

The current adder circuit 52 adds together the current signal IF3 and the current signal IF2 described above, and then outputs the resultant signal to the current control oscillating circuit 53 as the current signal IF4.

As a result, the current control oscillating circuit 53 sets low the frequency fₒᵤₜ of the pulse signal Fₒᵤₜ to be output in accordance with the decreased current value.

Next, at the time point t2, upon detecting that the control period has elapsed, the phase comparator circuit 1 stops outputting the control signal DN1 and the control signal DN2.

Due to the stop of input of the control signal DN1, the charge pump 2 sets the switch SW1D in the OFF-state, and then stops receiving the current signal IF1, which is the first discharge current.

Consequently, the discharge current stops flowing out of the loop filter 4. Accordingly, the loop filter 4 holds the current charged voltage, and then outputs this charged voltage to the voltage-current converter circuit 51 as the control voltage V1.

Then, the voltage-current converter circuit 51 converts the input control voltage V1 into the current IF3, and then outputs this current IF3 to the current adder circuit 52.

Further, due to the stop of input of the control signal DN2, similarly to the charge pump 2, the charge pump 3 sets the switch SW2D in the OFF-state, and then stops receiving the current signal IF2, which is the second discharge current.

As a result, with respect to the current adder circuit 52, the current signal IF2 is not output, and only the current signal IF3 is input. Accordingly, the current signal IF3 is output as the current signal IF4 without any alteration.

With the above-mentioned processing, the current control oscillating circuit 53 generates the frequency fₒᵤₜ in accordance with the pulse signal Fₒᵤₜ which has a frequency corresponding to the current value of the current signal IF3.

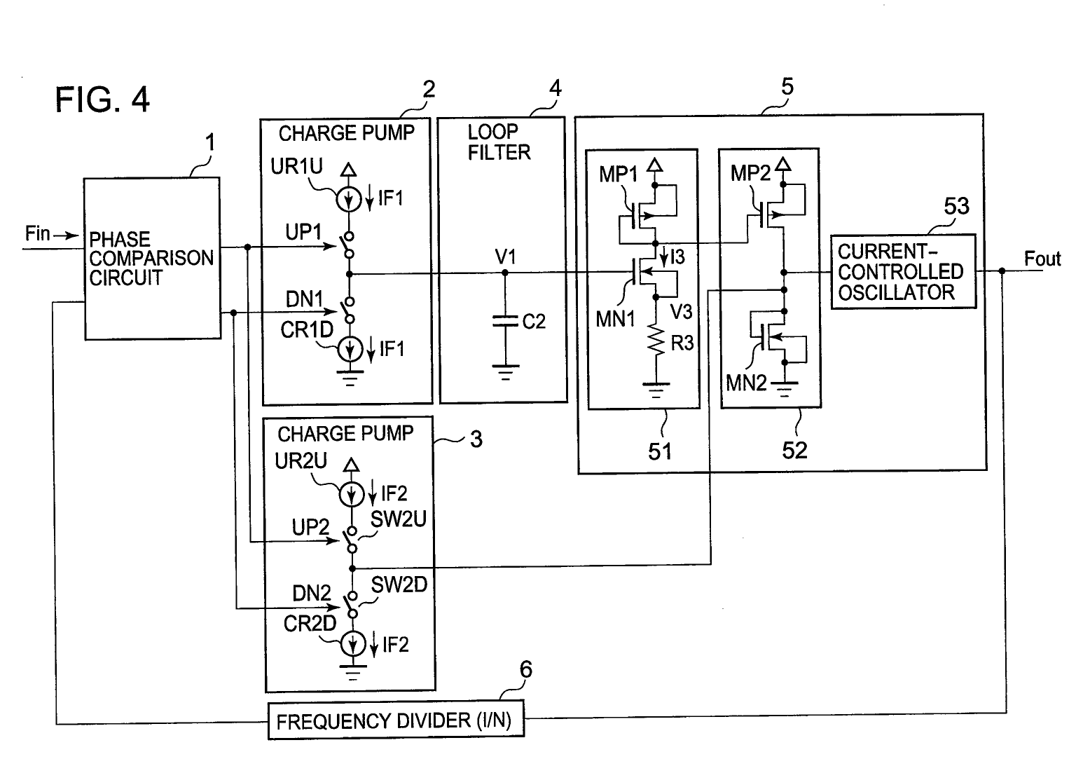

Next, with reference to FIG. 4, configuration examples of the voltage-current converter circuit 51 and the current adder circuit 52 of FIG. 1 are described.

The same components as those of FIG. 1 are denoted by the same reference symbols, and therefore the description thereof is omitted.

The voltage-current converter circuit 51 includes a p-channel MOS transistor MP1, an n-channel MOS transistor MN1, and a resistor R3.

The above-mentioned MOS transistor MP1 has a source connected to the power supply voltage, and has a gate and a drain connected to each other, which is called diode connection.

The above-mentioned MOS transistor MN1, which has a drain connected to the drain of the above-mentioned MOS transistor MP1 and a source connected to a well on which the MOS transistor MN1 itself is formed, is connected to the ground via a resistor R3.

With the above-mentioned configuration, the voltage-current converter circuit 51 serves as a bias generation circuit of a current mirror circuit which is configured of the voltage-current converter circuit 51 and the current adder circuit 52, and outputs to the current adder circuit 52 a bias voltage for causing a copy of the current signal IF3 (V1/r3 in FIGS. 2 and 3: r3 is a resistance value of the resistor R3) corresponding to the control voltage V1 to flow into the current adder circuit 52.

Further, the current adder circuit 52 includes a p-channel MOS transistor MP2 and an n-channel MOS transistor MN2.

The MOS transistor MP2 has a source connected to the power supply voltage, and the bias voltage which is output from the above-mentioned voltage-current converter circuit 51 is applied to a gate of the MOS transistor MP2.

The MOS transistor MN2 has a drain connected to a drain of the above-mentioned MOS transistor MP2, a gate connected to the drain thereof (diode connection), and a source connected to the ground. Further, the drain of the MOS transistor MN2 is connected to the output terminal of the charge pump 3, whereby the current signal IF2 is input or output.

With this configuration, the current adder circuit 52 outputs the current signal IF4 to the current control oscillating circuit 53, as a result of adding the respective current values of the above-mentioned current signal IF2 and the current corresponding to the current signal IF3 which flows out of the voltage-current converter circuit 51 of the current mirror configuration.

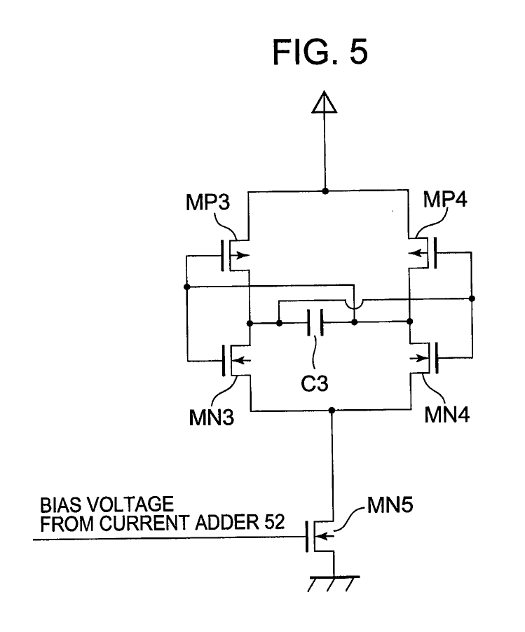

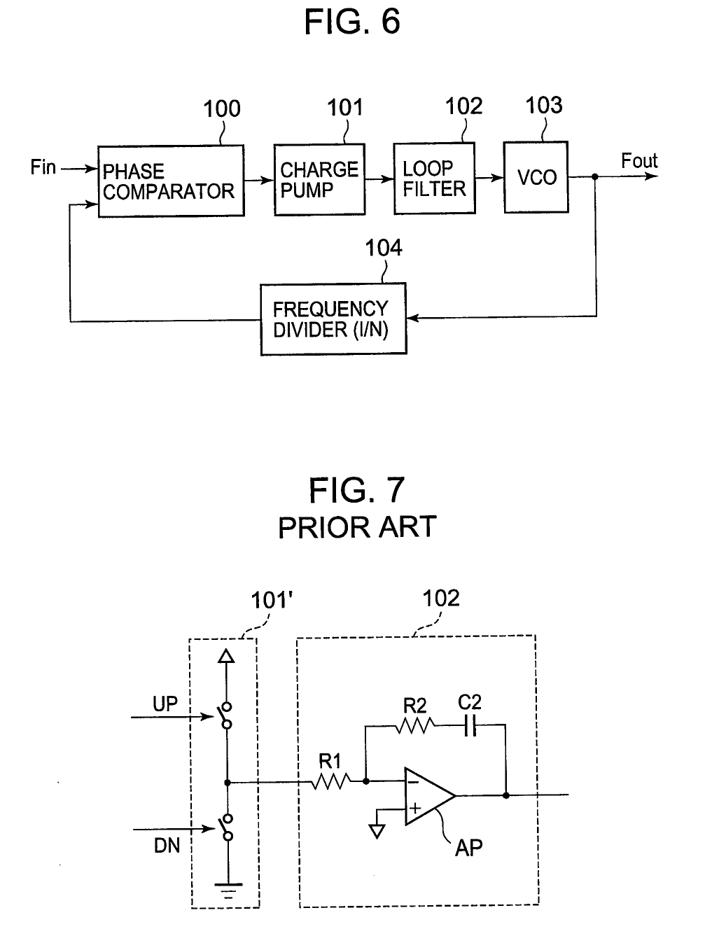

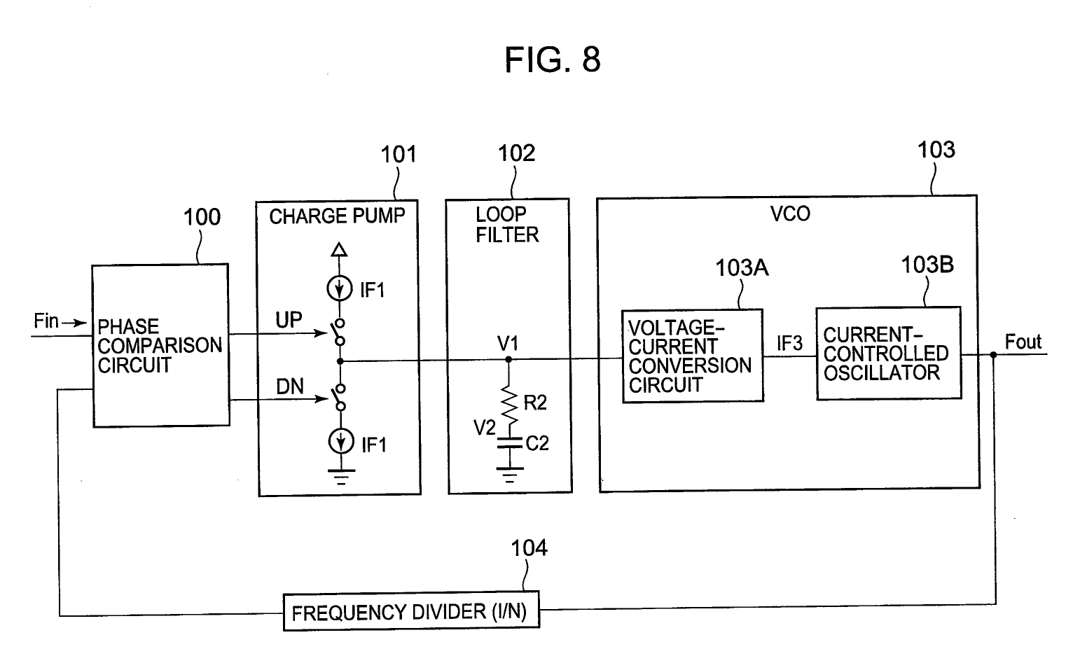

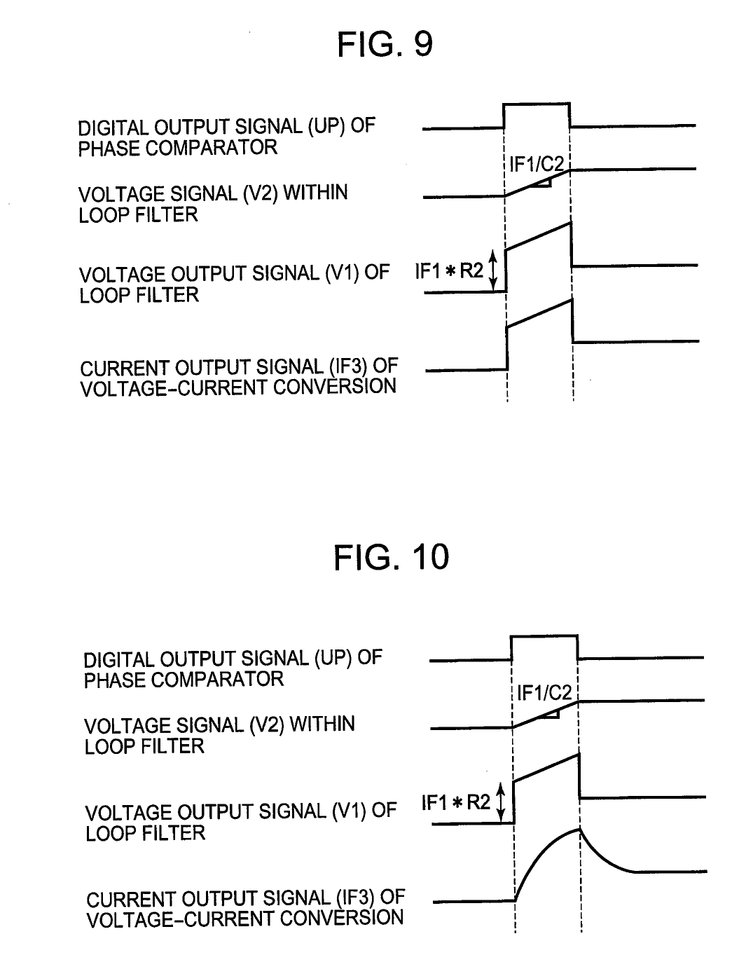

Next, the current control oscillating circuit 53 of FIGS. 1 and 4 is described. FIG. 5 is a conceptual circuit diagram for describing a configuration example of the current control oscillating circuit 53 of FIGS. 1 and 4.

The current control oscillating circuit 53 includes a p-channel MOS transistor MP3, a p-channel MOS transistor MP4, an n-channel MOS transistor MN3, an n-channel MOS transistor MN4, an n-channel MOS transistor MN5, and a capacitor C3.

The MOS transistor MP3 has a source connected to the power supply voltage, and has a gate connected to a drain of the MOS transistor MP4.

The MOS transistor MN3 has a drain connected to a drain of the above-mentioned MOS transistor MP3, a gate connected to the gate of the MOS transistor MP3, and a source connected to a drain of the MOS transistor MN5.

The MOS transistor MP4 has a source connected to the power supply voltage, and has a gate connected to the drain of the MOS transistor MP3.

The MOS transistor MN4 has a drain connected to the drain of the MOS transistor MP4, a gate connected to the gate of the MOS transistor MP4, and a source connected to the drain of the MOS transistor MN5.

The capacitor C3 is inserted between the drain of the MOS transistor MN3 and the drain of the MOS transistor MN4.

The MOS transistor MN5 has a source connected to the ground, and a bias voltage for causing a current corresponding to the current signal IF4 to flow from the current adder circuit 52 is applied to a gate of the MOS transistor MN5.

With the above-mentioned configuration, the MOS transistor MN5 operates as a current mirror based on the current (IF4) which is obtained by the addition and is output from the current adder circuit 52. Accordingly, when the current (IF4) is decreased, a charge/discharge period of the capacitor C3 becomes longer, whereby the oscillation frequency fₒᵤₜ is made lower. On the other hand, when the current (IF4) is increased, the charge/discharge period of the capacitor C3 becomes shorter, whereby the oscillation frequency fₒᵤₜ is made higher.

The current value of the current signal IF4 output from the current adder circuit 52 can be determined by the following Expression (1) (function which varies depending on time).

IF4=IF3±IF2=(V1/r3)±IF2 (1)

The present invention is not limited to the configuration made of the voltage-current converter circuit 51, the current adder circuit 52, and the current control oscillating circuit 53 described in this embodiment, and may be applicable to any configuration as long as the same operation is achieved.

What is claimed is:

1. A phase-locked loop circuit comprising:
a voltage control oscillating circuit comprising:
a voltage-current converter circuit;
a current adder; and
a current control oscillating circuit,
the voltage control oscillating circuit outputting a pulse having a frequency corresponding to a control voltage and a control current;
a phase detector which outputs a first control signal and a second control signal based on a phase difference between the pulse and a reference pulse having a frequency which should be generated by the voltage control oscillating circuit;
a first charge pump circuit which outputs one of a first charge current and a first discharge current in accordance with the first control signal;
a loop filter which generates the control voltage in accordance with the one of the first charge current and the first discharge current, and then outputs the generated control voltage to the voltage control oscillating circuit; and
a second charge pump circuit which generates the control current serving as one of a second charge current and a second discharge current in accordance with the second control signal, and then outputs the generated control current to the voltage control oscillating circuit.

2. A phase-locked loop circuit according to claim 1, wherein:
the voltage-current converter circuit converts the control voltage into a current; and
the current adder adds together the converted current and the control current to supply a current obtained by the adding to the current control oscillating circuit as a frequency control current.

3. A phase-locked loop circuit according to claim 1, wherein the loop filter comprises a capacitor which is inserted between an output terminal of the first charge pump circuit and a ground point.

4. A phase-locked loop circuit according to claim 2, wherein the loop filter comprises a capacitor which is inserted between an output terminal of the first charge pump circuit and a ground point.
